(19) United States
(12) Patent Application Publication
(10) Pub. No.: US 2002/0001910 A1
(43) Pub. Date: Jan. 3, 2002

(54) METHOD OF FORMING A MOS TRANSISTOR OF A SEMICONDUCTOR

(76) Inventors: CHIN-LAI CHEN, TAOYUAN HSIEN (TW); TONY LIN, KAOHSIUNG HSIEN (TW); JIH-WEN CHOU, HSIN-CHU (TW)

Correspondence Address: WINSTON HSU, SF. 389, FU-HO ROAD, YUNGHO CITY, TAIPEI, TW

(21) Appl. No.: 09/257,533

(22) Filed: Feb. 24, 1999

(51) Int. Cl. H01L 21/336

(52) U.S. Cl. 438/305

(57) ABSTRACT

The present invention provides a method of forming a MOS transistor on a substrate of a semiconductor wafer. The method comprises forming a rectangular-shaped gate on the substrate, forming a spacer at each of two opposite sides of the gate on the substrate, performing a first ion implantation process to form a source and a drain at predetermined positions of the substrate beside the two spacers, performing a first thermal annealing process on the semiconductor wafer, removing the spacers from the two sides of the gate, performing a second ion implantation process on the substrate to form a conducting layer below each of the spacers wherein one conducting layer is electrically connected with the source and another conducting layer is electrically connected with the drain, and performing a second thermal annealing process on the semiconductor wafer for activating implants of the second ion implantation process in the two conducting layers.

### BACKGROUND OF THE INVENTION

1. Field of the invention

The present invention relates to a MOS (metal-oxide-semiconductor) transistor, and more particularly, to a method of forming a MOS transistor of a semiconductor wafer.

2. Description of the Prior Art

MOS transistors are currently the most important semiconductor components. An integrated circuit (IC) usually contains several million MOS transistors. In the interest of cost cutting in IC production, attempts have been made to minimize the area of the MOS transistors on the semiconductor wafer.

Please refer to FIG. 1. FIG. 1 is a cross-sectional view of a MOS transistor 20 of a prior art semiconductor wafer 10. The semiconductor wafer 10 comprises a silicon substrate 23, and a MOS transistor 20 formed on the surface of the silicon substrate 23. The MOS transistor 20 comprises a rectangular-shaped gate 21, two spacers 22, a source 26, a drain 28 and two separate doped areas 24. In the process of forming the MOS transistor 20, the gate 21 is first formed on the surface of the silicon substrate 23, then a lightly doped drain (LDD) or a highly doped drain (HDD) ion implantation process is performed on the surface of the silicon substrate 23 to form the two separate doped areas 24 beside the gate 21 on the surface of the silicon substrate 23 to reduce the hot carrier effect. The two spacers 22 are then formed at two sides of the gate 21 on the surface of the silicon substrate 23. Then, each of the source 26 and drain 28 is formed on the surface of the silicon substrate 23 by an ion implantation process to electrically connect with one of the doped areas 24. Finally, a thermal annealing process is performed on the semiconductor wafer 10 to activate the dopants implanted in the source 26 and the drain 28 and also to repair structural damages of the surface of the silicon substrate 23 caused by the ion implantation.

With the increasing demand for reduced surface area of the MOS transistor 20, the depletion region of the source 26 and the drain 28 will almost overlap with the channel under the gate 21 thus causing a short channel effect. This further reduces the threshold voltage of the MOS transistor 20. The smaller the area of the MOS transistor 20, the more implants are needed to be implanted in the source 26 and the drain 28 in order to reduce the width of the depletion region. However, increasing the quantity of the dopants in the source 26 and the drain 28 also increases the capacitance of the source 26 and the drain 28 to the silicon substrate 23. This leads to a decrease in the operational speed of the MOS transistor 20. In addition, during the annealing process, the MOS transistor 20 is exposed to very high temperatures for extended periods of time. This causes the dopants in the doped areas 24 to diffuse outward thus decreasing the electrical channel beneath the gate 21. A short channel effect results, particularly with MOS transistors with smaller areas.

### SUMMARY OF THE INVENTION

It is therefore a primary objective of the present invention to provide a method of forming a MOS transistor on a semiconductor wafer to solve the above mentioned problems.

In a preferred embodiment, the present invention provides a method of forming a metaloxide-semiconductor (MOS) transistor on a substrate of a semiconductor wafer, the method comprising:

forming a rectangular-shaped gate on the substrate;

forming a spacer at each of two opposite sides of the gate on the substrate;

performing a first ion implantation process to form a source and a drain at predetermined positions of the substrate beside the two spacers;

performing a first thermal annealing process on the semiconductor wafer;

removing the spacers from the two sides of the gate;

performing a second ion implantation process on the substrate to form a conducting layer below each of the spacers wherein one conducting layer is electrically connected with the source, and another conducting layer is electrically connected with the drain; and

performing a second thermal annealing process on the semiconductor wafer for activating implants of the second ion implantation process in the two conducting layers.

It is an advantage of the present invention that the temperature and time needed for performing the thermal annealing process on the HDD or LDD doped areas are reduced leading to reduction of short channel effects and the area of the MOS transistor is also reduced thus decreasing costs.

This and other objectives of the present invention will no doubt become obvious to those of ordinary skill in the art after having read the following detailed description of the preferred embodiment which is illustrated in the various figures and drawings.

### BRIEF DESCRIPTION OF THE DRAWINGS

FIG. 1 is a cross-sectional view of a MOS transistor of a prior art semiconductor wafer.

FIG. 2 and FIG. 3 are cross-sectional views of a MOS transistor of a semiconductor wafer according to the present invention.

FIG. 4 is a flowchart of a process of forming the MOS transistor in FIG. 2.

FIG. 5 and FIG. 6 are cross-sectional views of another MOS transistor of a semiconductor wafer according to the present invention.

### DETAILED DESCRIPTION OF THE PREFERRED EMBODIMENT

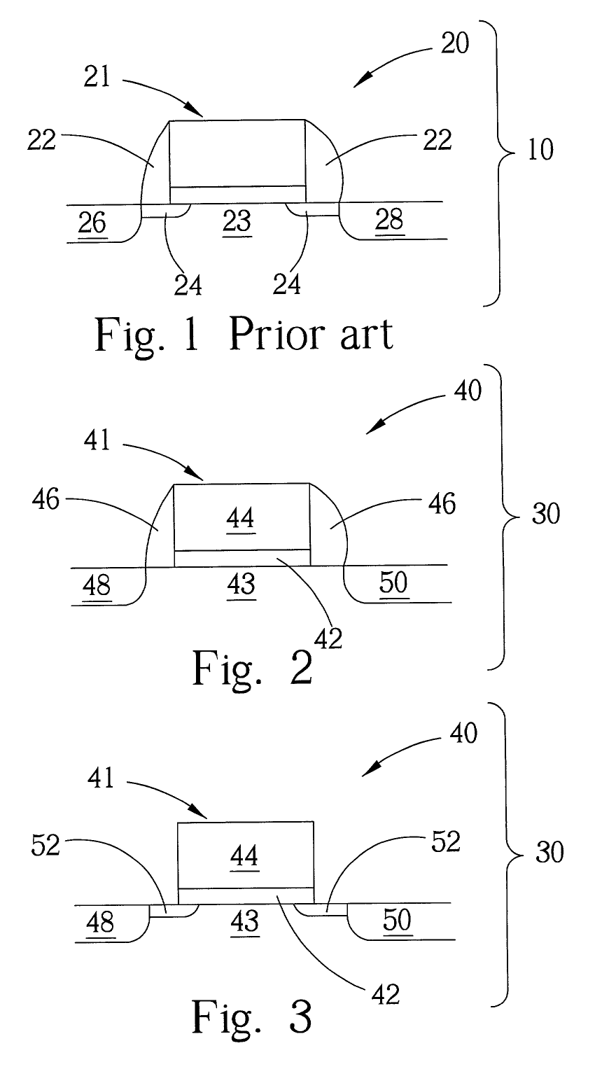

Please refer to FIG. 2 and FIG. 3. FIG. 2 and FIG. 3 are cross-sectional views of a MOS transistor 40 of a semiconductor wafer 30 according to the present invention. The semiconductor wafer 30 comprises a silicon substrate 43 and a MOS transistor 40 formed on the surface of the silicon substrate 43. The MOS transistor 40 comprises a rectangular-shaped gate 41, two spacers 46, a source 48, a drain 50, and two separate doped areas 52. The gate 41 comprises a gate oxide layer 42 formed of silicon oxide positioned on the silicon substrate 43 and a gate conducting layer 44 formed of poly-silicon positioned on the gate oxide layer 42.

In the process of forming the MOS transistor 40, the gate 41 is first formed on the substrate 43, then a spacer 46 made of silicon nitride is formed at each side of the gate 41 on the surface of the silicon substrate 43, an ion implantation process to implant implants is then performed to form the source 48 and the drain 50 at predetermined positions on the substrate 43 beside the two spacers 46.

After the source 48 and drain 50 are formed, a first thermal annealing process is performed on the semiconductor wafer 30 at a temperature of 900° C.˜1100° C. for 10˜30 seconds. The main purpose is to activate the implants implanted into the source 48 and drain 50 and to repair structural damages of the surface of the semiconductor wafer 30 caused by the ion implantation process. After completing the thermal annealing process, the spacers 46 are removed from the two sides of the gate 41 followed by a second ion implantation process on the substrate 43 to form a HDD or LDD conducting layer 52 below each of the spacers 46. One of these conducting layers is electrically connected with the source 48, and the other conducting layer is electrically connected with the drain 50.

Finally a second thermal annealing process is performed on the semiconductor wafer 30 through a spike rapid thermal process (spike RTP). In this process, the semiconductor wafer 30 is rapidly heated to a predetermined temperature between 800˜1100° C. for activating implants of the second ion implantation process in the two conducting layers 52, and then is cooled off to complete the process.

In the process of forming the MOS transistor 40, the source 48 and drain 50 are first formed followed by the first thermal annealing process. Because the first thermal annealing process is performed before performing HDD or LDD ion implantation, the subsequent activation of the implants of the HDD or LDD conducting layers 52 can be accomplished with the spike rapid thermal process which is completed in a lower temperature for a shorter period. This reduces the diffusion of the implants in the conducting layers 52 and prevents a short channel effect. Hence, with the same gate length, the channel length between the two conducting layers 52 of the MOS transistor 40 of the present invention is longer than that of the prior art MOS transistor 20. Therefore, using this method of forming a MOS transistor, a more stable threshold voltage is obtained with a smaller MOS transistor. This reduces costs.

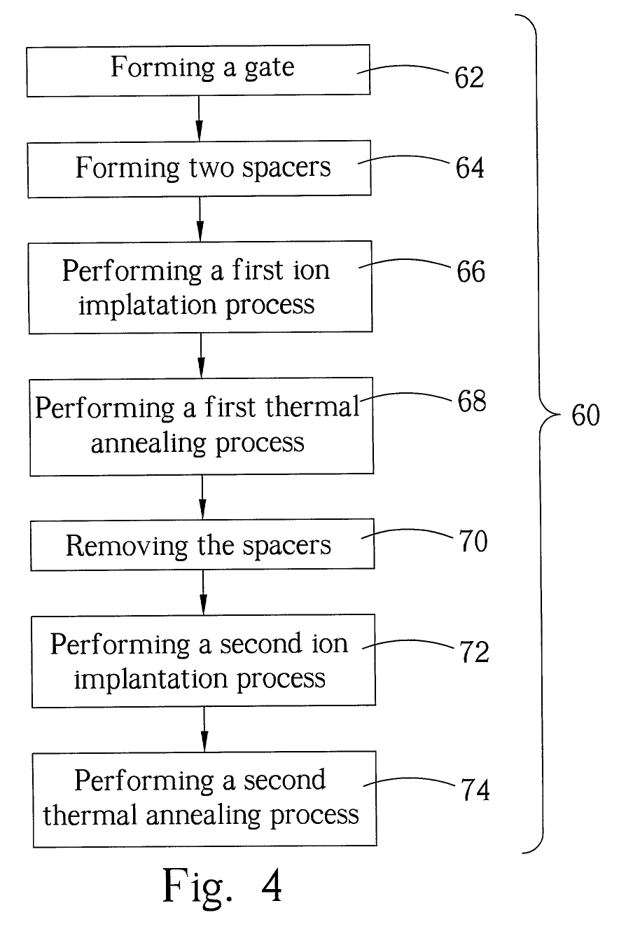

Please refer to FIG. 4. FIG. 4 is a flowchart of a process 60 of forming the MOS transistor 40 according to the present invention. The process 60 of forming the MOS transistor 40 comprises the following steps:

Step 62: forming a rectangular-shaped gate 41 on the substrate 43;

Step 64: forming a spacer 46 at each of two opposite sides of the gate 41;

Step 66: performing a first ion implantation process to form a source 48 and a drain 50 at predetermined positions of the substrate 43 beside the two spacers 46;

Step 68: performing a first thermal annealing process on the semiconductor wafer 30 at a temperature of 900° C.˜1100° C. for a time period of 10˜30 seconds;

Step 70: removing the spacers 46 from the two sides of the gate 41;

Step 72: performing a second ion implantation process on the substrate 43 to form a conducting layer 52 below each of the spacers 46 wherein one conducting layer is electrically connected with the source 48, and the other conducting layer is electrically connected with the drain 50; and

Step 74: performing a second thermal annealing process on the semiconductor wafer 30 wherein the semiconductor wafer is heated rapidly to a predetermined temperature between 800° C.˜1100° C. and then is cooled off; this process activates implants of the second ion implantation process in the two conducting layers 52.

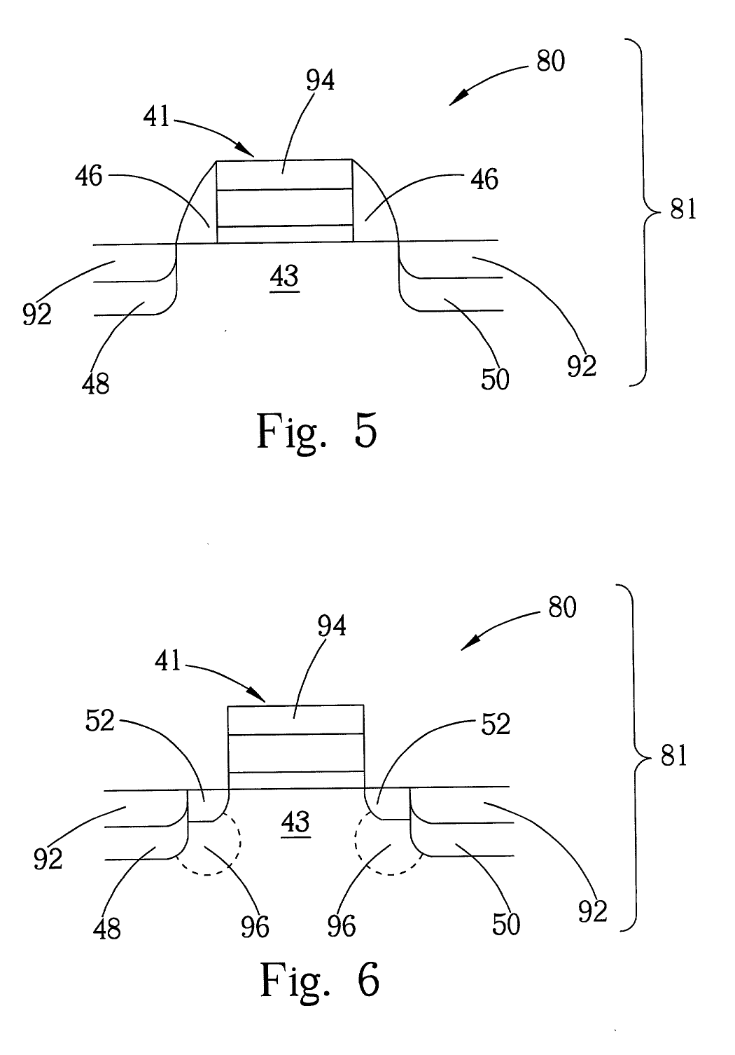

The process 60 of forming the MOS transistor can be applied to processes involving salicide and halo implantation. Please refer to FIG. 5 and FIG. 6. FIGS. 5 and 6 are cross-sectional views of another MOS transistor 80 on a semiconductor wafer 81 according to the present invention. As seen in the method of forming a MOS transistor 40 illustrated in FIG. 2. The MOS transistor 80 is formed by forming a gate 41, a source 48 and a drain 50 on the surface of the silicon substrate 43 of the semiconductor wafer 81, performing a thermal annealing process for the source 48 and the drain 50, performing a self-aligned silicidation process to form metallic silicide layers 92 and 94 separately on the surfaces of the source 48, the drain 50 and the gate 41 by WSiₓ, TiSi₂, MoSi₂ or CoSi₂ for reducing their resistance, and removing the two spacers 46 from the two opposite sides of the gate 41. After removing the spacers 46, HDD or LDD ion implantation and halo implantation processes are performed to implant dopants into the silicon substrate 43. The halo implantation process is performed by implanting dopants with the same electrical polarity as the silicon substrate 43 below the source 48 and the drain 50 to form two highly doped areas 96.

Because the surface of the source 48 and the drain 50 has a metallic silicide layer 92 within the MOS transistor, during the halo implantation process, it is more difficult for the implants to penetrate into the source 48 and the drain 50. Therefore, they will concentrate to form two highly doped areas 96 below the two HDD or LDD conducting layers 52. This can inhibit the occurrence of abnormal punch through between the source 48 and the drain 50, decrease the concentration of the PN junction between the bottom side of the source 48 and the drain 50 and the silicon substrate 43, decrease the PN junction capacitance and thus increase the operational speed of the MOS transistor 80.

In contrast to the prior art, the process of forming the MOS transistor 40, 80 performs the annealing process of the source and the drain and the annealing process of the HDD or LDD conducting layer separately, so the dopants of the HDD or LDD conducting layer will only experience the spike rapid thermal annealing process thus short channel effects are prevented. Hence the MOS transistor formed by the present process not only has a stable threshold voltage but also uses a smaller area. This reduces costs.

Those skilled in the art will readily observe that numerous modifications and alterations of the device may be made while retaining the teaching of the invention. Accordingly, the above disclosure should be construed as limited only by the metes and bounds of the appended claims.

What is claimed is:

1. A method of forming a metal-oxide-semiconductor (MOS) transistor on a substrate of a semiconductor wafer, the method comprising:
forming a rectangular-shaped gate on the substrate;
forming a spacer at each of two opposite sides of the gate on the substrate;
performing a first ion implantation process to form a source and a drain at predetermined positions of the substrate beside the two spacers;
performing a first thermal annealing process on the semiconductor wafer;
removing the spacers from the two sides of the gate;
performing a second ion implantation process on the substrate to form a conducting layer below each of the spacers wherein one conducting layer is electrically connected with the source, and another conducting layer is electrically connected with the drain; and
performing a second thermal annealing process on the semiconductor wafer for activating implants of the second ion implantation process in the two conducting layers.

2. The method of claim 1 wherein the first thermal annealing process is performed at a temperature of 900° C.˜1100° C. for a time period of 10˜30 seconds.

3. The method of claim 1 wherein the second thermal annealing process is a rapid thermal process which heats the semiconductor wafer rapidly to a predetermined temperature and then starts cooling the semiconductor wafer.

4. The method of claim 3 wherein the predetermined temperature is between 800° C.˜1100° C.

5. The method of claim 1 wherein the two spacers are formed by silicon nitride.

6. The method of claim 1 wherein before removing the spacers at the two sides of the gate, the method further comprises:
forming a metallic silicide layer on the gate, source and drain to reduce their resistance.

7. The method of claim 6 wherein the metallic silicide layer is formed by WSiₓ, TiSi₂, MoSi₂ or CoSi₂.

8. The method of claim 6 wherein the metallic silicide layer is formed by a self-aligned silicidation process.

9. The method of claim 1 wherein the gate comprises a gate oxide layer positioned on the substrate and a gate conducting layer positioned on the gate oxide layer.

10. The method of claim 9 wherein the gate oxide layer is formed by silicon dioxide.

11. The method of claim 9 wherein the gate conducting layer is formed by polysilicon.
